(19) United States
(12) Patent Application Publication
(10) Pub. No.: US 2012/0092602 A1
(43) Pub. Date: Apr. 19, 2012

(54) MANUFACTURING METHOD OF LIQUID CRYSTAL DISPLAY DEVICE AND LIQUID CRYSTAL DISPLAY DEVICE

(75) Inventors: Tomoko AKAGAWA, Suwa (JP); Nobukazu NAGAE, Suwa (JP)

(73) Assignee: SEIKO EPSON CORPORATION, Tokyo (JP)

(21) Appl. No.: 13/230,057

(22) Filed: Sep. 12, 2011

(30) Foreign Application Priority Data
Oct. 19, 2010 (JP) 2010-234250

(51) Int. Cl. G02F 1/1337; H01L 33/08

(52) U.S. Cl. 349/125; 438/30; 257/E33.067

(57) ABSTRACT

A manufacturing method of a liquid crystal display device including a liquid crystal layer sandwiched between a pair of opposed substrates and orientation films includes forming a first orientation film having straight-chain alkyl chains at the liquid crystal layer side of one substrate, and forming a second orientation film at the liquid crystal layer side of the other substrate by forming an inorganic orientation layer and surface-treating the inorganic orientation layer using a silane coupling agent, and forming the second orientation film includes surface-treating the inorganic orientation layer using a first silane coupling agent having straight-chain alkyl chains and surface-treating the layer using a second silane coupling agent having straight-chain alkyl chains and having only one hydrolytic group.

### BACKGROUND

1. Technical Field

The present invention relates to a manufacturing method of a liquid crystal display device and a liquid crystal display device.

2. Related Art

In related art, liquid crystal panels have been used for many displays (display apparatuses) such as televisions, monitors, and cameras. In the liquid crystal panel (liquid crystal display apparatus), pixel electrodes and a common electrode are formed on a pair of substrates, a liquid crystal layer is sandwiched between the electrodes, and orientation films are respectively formed on the inner surfaces of the respective substrates, i.e., on the liquid crystal layer sides of the respective electrodes.

In the liquid crystal panel having the above described configuration, improvements of various properties are requested, and the improvement of reliability is one of the issues. Particularly, since a liquid crystal panel used for a projector is necessary to be driven with high brightness under a high-temperature environment, recently, liquid crystal panels with orientation films formed using inorganic materials such as SiO₂ for dealing with the environment have been put into production. As methods of forming the orientation films of inorganic materials such as SiO₂, vacuum processes such as oblique evaporation using vacuum systems are generally employed.

Regarding the orientation films of inorganic materials, for example, for the purpose of improvement in durability, alkylation of the surface of the SiO₂ film using a silane coupling agent or the like has been proposed (for example, see Patent Document 1 (JP-A-2008-83325) and Patent Document 2 (JP-A-2010-20093)).

Further, recently, for the purpose of cost reduction, a method of forming the orientation film of one substrate of the pair of substrates using an inorganic material film by a vacuum process and forming the other orientation film by a coating process using a coating material containing SiO₂ having alkyl chains has been also proposed (for example, see Patent Document 3 (JP-2009-223139)).

However, when one orientation film is formed by the vacuum process and the other orientation film is formed by the coating process as in Patent Document 3, the orientation films are different between the pair of substrates and charged states are different between the orientation films, and the voltage between the substrates (electrodes) changes over time. Then, a condition becomes such that one electrode side is biased, and display properties change over time and reliability is deteriorated.

### SUMMARY

An advantage of some aspects of the invention is to provide a liquid crystal display device with improved reliability in which the voltage change over time between a pair of substrates (electrodes) is suppressed while cost reduction is realized, and a manufacturing method thereof.

The inventors have obtained the following finding as a result of earnest studies in achieving the advantage.

It has been considered that the voltage between the pair of substrates (electrodes) changes over time because ionic impurities gradually accumulate at one orientation film side due to the difference of orientation films between the substrates, and thereby, charge is accumulated and charged states become different between the orientation films.

Further, it has been considered that the ionic impurities are gradually accumulated because, when the SiO₂ film is formed by the vacuum process and the surface of the SiO₂ film is alkylated using the silane coupling agent, and thereby, the orientation film is obtained, many silanol groups are left on the surface of the SiO₂ film. That is, it has been considered that the residual silanol groups become active sites and the ionic impurities react and adhere thereto, and thereby, charge is accumulated.

An aspect of the invention is directed to a manufacturing method of a liquid crystal display device including a liquid crystal layer sandwiched between a pair of opposed substrates with orientation films respectively provided between the pair of substrates and the liquid crystal layer, and the method includes forming a first orientation film having straight-chain alkyl chains using a coating process at the liquid crystal layer side of one substrate of the pair of substrates, and forming a second orientation film at the liquid crystal layer side of the other substrate of the pair of substrates by forming an inorganic orientation layer using a vacuum process, and then, surface-treating the inorganic orientation layer using a silane coupling agent, wherein forming the second orientation film includes surface-treating the inorganic orientation layer using a first silane coupling agent having straight-chain alkyl chains, and then, surface-treating the layer using a second silane coupling agent having straight-chain alkyl chains and having only one hydrolytic group.

According to the manufacturing method of the liquid crystal display device, the second orientation film is formed by surface-treating the inorganic orientation layer formed by the vacuum process using the first silane coupling agent, and then, surface-treating the layer using the second silane coupling agent having only one hydrolytic group. Therefore, for example, after the surface treatment of the inorganic orientation layer of the SiO₂ film using the first silane coupling agent, if many silanol groups are left on the surface of the SiO₂ film, the surface treatment is then performed thereon using the second silane coupling agent, and thereby, the second silane coupling agent is reacted with the residual silanol groups and the residual silanol groups to be active sites may be reduced sufficiently.

Further, in the case where the first silane coupling agent has plural hydrolysis groups, since the first silane coupling agent has other hydrolytic groups than the hydrolytic groups that have reacted with the silanol groups on the SiO₂ film surface, the hydrolytic groups may become new silanol groups. However, the second silane coupling agent also reacts with the silanol groups derived from the first silane coupling agent, and the residual silanol groups to be active sites may be reduced.

Furthermore, since the second silane coupling agent has only one hydrolysis group, after the hydrolytic group reacts with the silanol group on the SiO₂ film surface or the silanol group derived from the first silane coupling agent, a new silanol group derived from the second silane coupling agent is no longer formed.

Therefore, silanol groups do not remain on the second orientation film in a large amount and the voltage change over time between the pair of substrates (electrodes) caused thereby may be suppressed.

Further, in the manufacturing method of the liquid crystal display device, it is preferable that a carbon number of the straight-chain alkyl chains of the second silane coupling agent is less than a carbon number of the straight-chain alkyl chains of the first silane coupling agent.

In this manner, the second silane coupling agent easily reacts with and adheres to the inorganic orientation layer without causing steric hindrance to the first silane coupling agent adhering to the inorganic orientation layer.

Furthermore, in the manufacturing method of the liquid crystal display device, it is preferable that a treatment temperature at surface treatment using the second silane coupling agent is lower than a treatment temperature at surface treatment using the first silane coupling agent.

In this manner, compounds derived from the first silane coupling agent is prevented from desorbing from the inorganic orientation layer at the surface treatment using the second silane coupling agent.

Another aspect of the invention is directed to a liquid crystal display device including a liquid crystal layer sandwiched between a pair of opposed substrates with orientation films respectively provided between the pair of substrates and the liquid crystal layer, a first orientation film having straight-chain alkyl chains formed using a coating process at the liquid crystal layer side of one substrate of the pair of substrates, and a second orientation film at the liquid crystal layer side of the other substrate of the pair of substrates, wherein the second orientation film is formed by surface-treating an inorganic orientation layer formed by a vacuum process using a first silane coupling agent having straight-chain alkyl chains, and then, surface-treating the layer using a second silane coupling agent having straight-chain alkyl chains and having only one hydrolytic group.

According to the liquid crystal display device, since the device has the second orientation film formed by surface-treating the inorganic orientation layer formed by the vacuum process using the first silane coupling agent, and then, surface-treating the layer using the second silane coupling agent having only one hydrolytic group, in the second orientation film, the residual silanol groups to be active sites are sufficiently reduced.

Further, since the second silane coupling agent also reacts with the silanol groups derived from the first silane coupling agent, the residual silanol groups to be active sites are reduced.

Furthermore, since the second silane coupling agent has only one hydrolytic group, after the hydrolytic group reacts with the silanol group on the SiO₂ film surface or the silanol group derived from the first silane coupling agent, a new silanol group derived from the second silane coupling agent is no longer formed.

Therefore, silanol groups do not remain on the second orientation film in a large amount and the voltage change over time between the pair of substrates (electrodes) caused thereby may be suppressed.

### BRIEF DESCRIPTION OF THE DRAWINGS

The invention will be described with reference to the accompanying drawings, wherein like numbers reference like elements.

FIG. 1 is a side sectional view showing an example of a liquid crystal display apparatus according to the invention.

FIG. 2A is a side sectional view showing a schematic configuration of an opposed substrate, and FIG. 2B is a schematic diagram of the same.

FIG. 3A is a side sectional view showing a schematic configuration of a device substrate, and FIG. 3B is a schematic diagram of the same.

FIGS. 4A to 4C are explanatory diagrams of a manufacturing process of a second orientation film.

FIG. 5 is a graph showing experimental results.

### DESCRIPTION OF EXEMPLARY EMBODIMENTS

As below, an embodiment of the invention will be explained with reference to the drawings. Note that scales are varied with respect to each member for showing the respective members in recognizable sizes on the drawings.

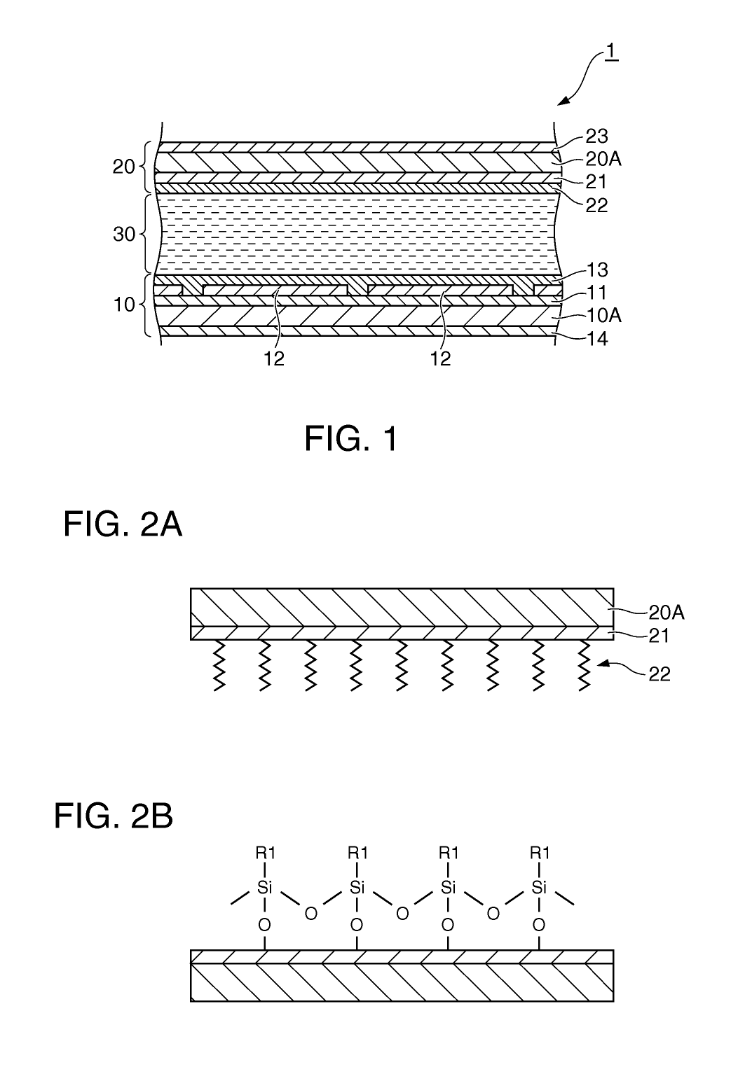

FIG. 1 is a side sectional view showing an example of a liquid crystal display apparatus according to the invention, the sign “1” denotes a liquid crystal display apparatus in FIG. 1. The liquid crystal display apparatus 1 has many liquid crystal display devices, and includes a device substrate 10, an opposed substrate 20 oppositely provided to the device substrate 10, and a liquid crystal layer 30 sandwiched between the pair of substrates 10, 20. Note that the liquid crystal display apparatus 1 is a transmissive-type apparatus and the opposed substrate 20 side is a light incident side and the device substrate 10 side is a light exit side.

The device substrate 10 has a transparent substrate 10A as a base, the other substrate in the invention, and is an active-matrix-type substrate. On the liquid crystal layer 30 side of the transparent substrate 10A, a device formation layer 11 is provided. Though the detailed structure of the device formation layer 11 is not shown, the device formation layer 11 includes switching elements such as thin-film transistors (TFTs) or the like, various lines such as data lines and scanning lines, etc. The TFT is electrically connected to a supply source of an image signal via the data line, and electrically connected to a supply source of a control signal via the scanning line.

On the liquid crystal layer 30 side in the device formation layer 11, plural island-shaped pixel electrodes 12 of ITO are formed, and these pixel electrodes 12 are electrically connected to the TFTs. Further, on the device formation layer 11, a second orientation film 13 is provided to cover the pixel electrodes 12. On the opposite side to the liquid crystal layer 30 of the transparent substrate 10A, a polarizer 14 is provided.

The opposed substrate 20 has a transparent substrate 20A as a base, one substrate in the invention. On the liquid crystal layer 30 side of the transparent substrate 20A, a common electrode 21 of ITO is provided and, on the liquid crystal layer 30 side of the common electrode 21, a first orientation film 22 is provided. Further, on the opposite side to the liquid crystal layer 30 of the transparent substrate 20A, a polarizer 23 is provided.

In the liquid crystal display apparatus 1 having the above described configuration, the device substrate 10 and the opposed substrate 20, one pixel electrode 12 and a corresponding part of the common electrode 21, and the second orientation film 13, the liquid crystal layer 30, and the first orientation film 22 provided between the pixel electrode 12 and the part of the common electrode 21 form the liquid crystal display device according to the invention.

Note that the second orientation film 13 and the first orientation film 22 control orientation of liquid crystal molecules of the liquid crystal layer 30, and their details will be described later.

In the liquid crystal display apparatus 1, when the control signal is transmitted to the TFT of the device formation layer 11, the TFT is turned on and the image signal is transmitted to the pixel electrode 12. Then, an electric field in response to the image signal is applied between the pixel electrode 12 and the common electrode 21, and azimuth angles of the liquid crystal molecules are controlled by the electric field. The light entering from the opposed substrate 20 in this state becomes linearly-polarized light by the polarizer 23, and its polarization state changes due to modulation by the liquid crystal layer 30. Part of the modulated light is absorbed by the polarizer 14 in response to the polarization state and becomes light representing a predetermined gray level, and is output from the device substrate 10 side.

The first orientation film 22 at the opposed substrate 20 side is an orientation film without a specific azimuth angle as shown in FIG. 2A, for example, i.e., taking the nearly vertical orientation, and the surface of the common electrode 21 is modified with straight-chain alkyl chains R1 as shown in FIG. 2B. The first orientation film 22 is formed using a coating process such as spin coating or flexographic printing by coating the substrate main body 20A with an orientation film formation material.

As the orientation film formation material, a self-assembled compound, i.e., a silicon-series compound, organic silane, or the like having reactive groups that chemically adsorb (bond) to the common electrode 21 (for example, alkoxy groups providing silanol groups by hydrolysis) and sites that regulate orientation of the liquid crystal molecules (for example, the R1 including the alkyl groups with a number of carbon atoms of 10 to 20) is used.

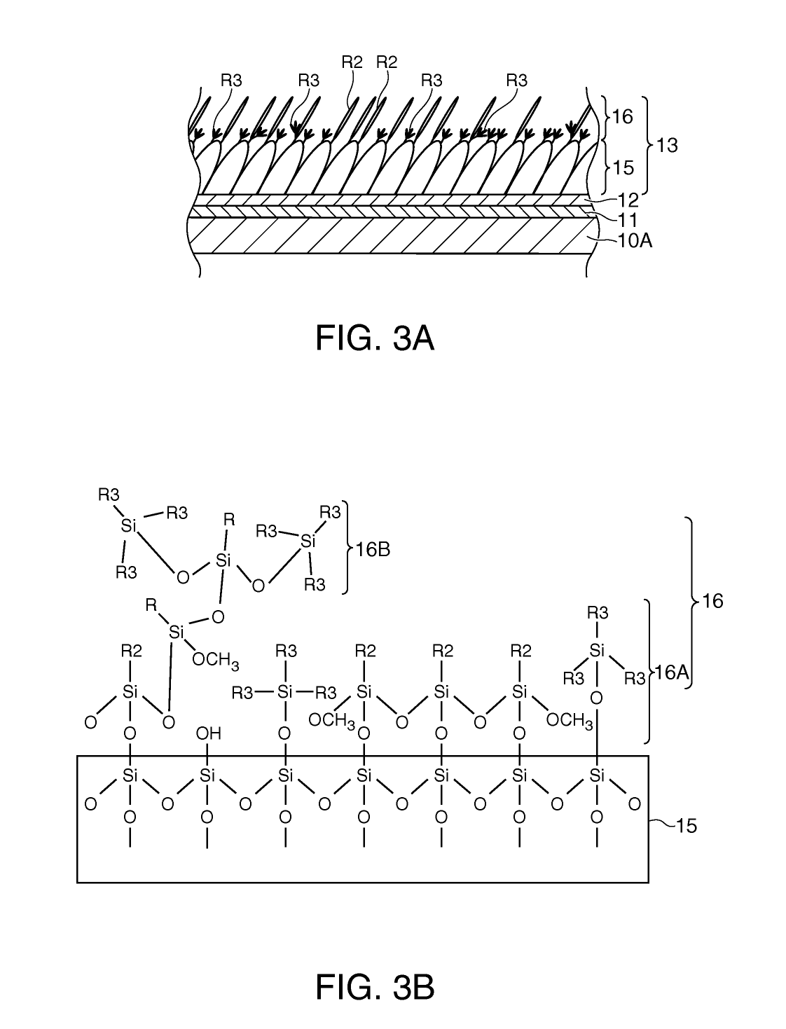

The second orientation film 13 at the device substrate 10 side includes an inorganic orientation layer 15 and a surface layer 16 as shown in FIGS. 3A and 3B. The inorganic orientation layer 15 is formed by evaporating an inorganic orientation film formation material on the substrate main body 10A using oblique evaporation. As the inorganic orientation film formation material, a silicon oxide of SiO₂ or SiO is used.

The surface layer 16 is formed on the inorganic orientation layer 15, and includes a first surface layer 16A having straight-chain alkyl chains R2 reacting with and bonding to the silanol groups (Si—OH) of the inorganic orientation layer 15, and a second surface layer 16B having straight-chain alkyl chains R3 reacting with and bonding to the silanol groups of the inorganic orientation layer 15 and the silanol groups of the first surface layer 16A. Note that, since the second surface layer 16B has a part directly bonded to the inorganic orientation layer 15, the first surface layer 16A and the second surface layer 16B are formed not by being simply stacked but by being mixed with each other.

The straight-chain alkyl chains R2, R3 forming the first surface layer 16A and the second surface layer 16B roughly reflect the surface profile of the inorganic orientation layer 15 formed by oblique evaporation. That is, the straight-chain alkyl chains R2, R3 extend (bond) nearly along the profile of the inorganic orientation layer 15, and thereby, have nearly the same pre-tilt (orientation regulation force of liquid crystal molecules) as that in the inorganic orientation layer 15.

Note that the first surface layer 16A and the second surface layer 16B are formed by surface treatment of the inorganic orientation layer 15 using the silane coupling agent as will be described later.

Next, a manufacturing method of the liquid crystal display apparatus having the above described configuration will be explained.

First, the transparent substrate 20A of glass or the like is prepared, and a light-blocking film (not shown) and the common electrode 21 are formed thereon using a known method.

Subsequently, the first orientation film 22 is formed on the common electrode 21, and thereby, the opposed substrate 20 is obtained. The formation of the first orientation film 22 is performed using the coating process such as spin coating or flexographic printing by coating the opposed substrate 20 with the orientation film formation material of a silicon-series compound containing straight-chain alkyl groups (straight-chain alkyl chains R1). In this manner, when the common electrode 21 of ITO is coated with the orientation film formation material, due to reaction of hydroxyl groups on the ITO surface with reactive groups (hydrolysis groups) such as alkoxyl groups or the like, a self-assembled monomolecular film (SAM) is formed on the transparent substrate 20A to cover the common electrode 21.

Specifically, by coating the substrate main body 20A with a methanol solution of octadecyl trimethoxysilane under an N₂ atmosphere, the SAM having alkyl groups to be straight-chain alkyl chains (octadecyl groups) may be formed on the common electrode 21. In this manner, on the substrate main body 20A, the first orientation film 22 having an organic-inorganic hybrid structure with a main-chain skeleton of Si is obtained.

For the coating process, various methods other than those described above may be employed, and, for example, dip coating methods, spray coating methods, various printing methods, inkjet methods, etc. may be employed.

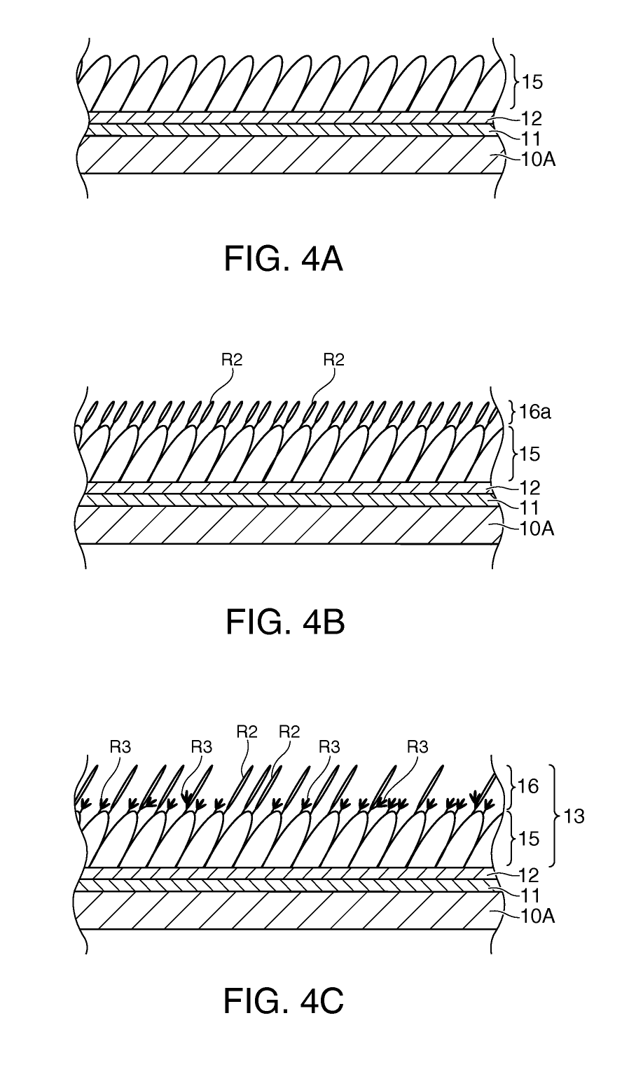

Further, the transparent substrate 10A of glass or the like is prepared, and a shielding film, a semiconductor layer, various lines such as data lines and scanning lines (none of them are shown), the pixel electrodes 12, etc. are formed thereon using a known method. Subsequently, as shown in FIG. 4A, oblique evaporation of SiO₂ is performed on the pixel electrodes 12 by a vacuum process using a vacuum deposition system, and the inorganic orientation layer 15 is formed. Specifically, within the vacuum deposition system, an angle formed by the deposition surface of the transparent substrate 10A and the incident direction of the deposition material relative to the deposition surface (incident angle) is set to be less than 90 degrees. As a result, oblique crystals of the deposition material (SiO₂) grow on the deposition surface, and thereby, a film having a desired oblique columnar structure (pre-tilt) may be formed. The inorganic orientation layer 15 is formed on the transparent substrate 10A in this manner, and then, surface treatment is performed on the inorganic orientation layer 15 and the device substrate 10 is formed.

In the surface treatment, first, the transparent substrate 10A with the inorganic orientation layer 15 formed thereon is treated using a first silane coupling agent having straight-chain alkyl groups (straight-chain alkyl chains). Here, the silane coupling agent has an organic functional group and a hydrolytic group in one molecule and couples inorganic materials and organic materials by the groups, and thereby, can improve physical strength, durability, adhesion, etc. Further, as the first silane coupling agent, an agent having one organic functional group and functional groups reacting with an inorganic material (hydrolytic groups) per silicon atom (Si) and expressed by the following formula is used

YSiX₃ (1)

X: a hydrolytic group bonded to a silicon atom, —OR, —Cl, —NR₂, or the like (R indicates an alkyl group)
Y: an organic functional group reacting with an organic matrix or the like, an alkyl group (—R).

It is necessary that, as the first silane coupling agent for use, the organic functional group has good water repellency and light resistance. Specifically, methyl trimethoxysilane, methyl triethoxysilane, ethyl trimethoxysilane, ethyl triethoxysilane, propyl trimethoxysilane, hexyl trimethoxysilane, octyl trimethoxysilane, decyl trimethoxysilane, dodecyl triethoxysilane, octadecyl trimethoxysilane, or the like may be used. Particularly, for good liquid repellency, the longer alkyl group (the straight-chain alkyl group R2) as the organic functional group (Y) is preferable and the decyl trimethoxysilane (C₁₀H₂₁Si (OCH₃)₃) is preferably used. Note that the silane coupling agent with hydrolytic groups of (—OR), (—Cl), (—NR₂) or the like in place of the alkoxy groups may be used.

For the surface treatment using the first silane coupling agent, a gas-phase method is preferably employed. Specifically, the transparent substrate 10A with the inorganic orientation layer 15 formed thereon and a container containing the first silane coupling agent are put into a chamber, and the chamber is enclosed. Then, the interior of the chamber is heated and evaporation of the first silane coupling agent is promoted, and thereby, the vapor of the first silane coupling agent is brought into contact with the inorganic orientation layer 15 surface for reaction. For example, surface treatment is performed using decyl trimethoxysilane as the first silane coupling agent and heating the interior of the chamber to 175° C. Thereby, as shown in FIG. 4B, silanol groups on the inorganic orientation layer 15 surface react with the hydrolytic groups (methoxy groups) of the first silane coupling agent, the first silane coupling agent adheres thereto, and the first surface layer 16A having straight-chain alkyl chains R2 (decyl groups) is formed on the inorganic orientation layer 15 surface.

However, even when the first silane coupling agent having the longer alkyl groups R2 is reacted with the inorganic orientation layer 15 to adhere to the surface thereof, it is difficult to react all silanol groups on the inorganic orientation layer 15 surface with the silane coupling agent due to steric hindrance by the alkyl groups or the like. Therefore, part of the silanol groups is left on the surface of the inorganic orientation layer 15 as unreacted silanol groups, i.e., active sites. Further, since the first silane coupling agent has three hydrolytic groups (methoxy groups) as described above, part of them are hydroxylated and become new silanol groups, i.e., silanol groups derived from the first silane coupling agent.

In the surface treatment for the inorganic orientation layer 15, then, the transparent substrate 10A that has been surface-treated using the first silane coupling agent is surface-treated using a second silane coupling agent having straight-chain alkyl groups (straight-chain alkyl chains). As the second silane coupling agent, different from the first silane coupling agent, an agent expressed by the following formula (2) is used.

Y₃SiX (2)

Note that the respective groups of X, Y are the same as those in Formula (1), and X is a hydrolytic group and Y is an alkyl group.

As expressed by Formula (2), the second silane coupling agent has only one hydrolytic group and other groups as alkyl groups. Specifically, trimethyl methoxysilane, vinyloxy trimethylsilane, vinyloxy triethylsilane, triethyl methoxysilane, triethyl ethoxysilane, octyl dimethyl methoxysilane, octadecyl dimethyl methoxysilane, or the like may be used. Note that the silane coupling agent with hydrolytic groups of (—OR), (—Cl), (—NR₂) or the like in place of the alkoxy groups may be used.

Further, it is preferable to use the second silane coupling agent having the carbon number of the straight-chain alkyl chains less than the carbon number of the straight-chain alkyl chains of the first silane coupling agent. This is because, compared to the first silane coupling agent adhered to the inorganic orientation layer 15, the second silane coupling agent is allowed to easily react with the silanol groups left on the inorganic orientation layer 15 surface without causing steric hindrance. In the embodiment, vinyloxy triethylsilane is preferably used.

For the surface treatment using the second silane coupling agent, a gas-phase method is preferably employed like the surface treatment using the first silane coupling agent. Specifically, the transparent substrate 10A that has been surface-treated using the first silane coupling agent is cleansed and dried, and then, like the surface treatment using the first silane coupling agent, the transparent substrate 10A and a container containing the second silane coupling agent are put into a chamber and the chamber is enclosed. Then, the interior of the chamber is heated and evaporation of the second silane coupling agent is promoted, and thereby, the vapor of the second silane coupling agent is brought into contact with the inorganic orientation layer 15 surface that has been surface-treated using the first silane coupling agent for reaction.

For example, surface treatment is performed using vinyloxy triethylsilane as the second silane coupling agent and heating the interior of the chamber to 130° C. Thereby, as shown in FIG. 3B, silanol groups left on the inorganic orientation layer 15 surface react with the hydrolytic groups (methoxy groups) of the second silane coupling agent and the second silane coupling agent adheres thereto. Further, the hydrolytic groups of the second silane coupling agent also react with the silanol groups derived from the first silane coupling agent and the second silane coupling agent adheres thereto. Thus, as shown in FIG. 4C, the second surface layer 16B having straight-chain alkyl chains R3 (ethyl groups) is formed on the inorganic orientation layer 15 surface.

Then, the transparent substrate 10A that has been surface-treated using the second silane coupling agent is cleansed, dried, and thereby, the device substrate 10 is obtained.

Here, at surface treatment using the second silane coupling agent, its treatment temperature, i.e., heating temperature is set lower than the treatment temperature at surface treatment using the first silane coupling agent. This is for preventing the compounds derived from the first silane coupling agent from desorbing from the inorganic orientation layer 15 at the surface treatment using the second silane coupling agent. In the case where the desorption hardly occurs, the temperature is not necessarily limited to the above described treatment temperature condition.

Note that the gas-phase method is employed as the treatment method in both of the surface treatment using the first silane coupling agent and the surface treatment using the second silane coupling agent, however, a liquid-phase method such as a dip coating method or spray coating method may be employed.

In this manner, the opposed substrate 20 is obtained by forming the first orientation film on the transparent substrate 20A and the device substrate 10 is obtained by forming the second orientation film on the transparent substrate 10A, and then, liquid crystal is injected between the substrates 10, 20 using a known method, and a liquid crystal panel is fabricated. Then, the polarizers 14, 23 etc. are provided, and the liquid crystal display apparatus 1 shown in FIG. 1 is formed. Note that, by forming the liquid crystal display apparatus 1, many liquid crystal display devices forming the liquid crystal display apparatus 1 may be formed at the same time.

According to the manufacturing method, the second orientation film is formed by surface-treating the inorganic orientation layer 15 formed by the vacuum process using the first silane coupling agent, and then, surface-treating the layer using the second silane coupling agent having only one hydrolytic group. Therefore, after the surface treatment of the inorganic orientation layer 15 using the first silane coupling agent, if many silanol groups are left on the surface thereof, the surface treatment is then performed thereon using the second silane coupling agent, and thereby, the second silane coupling agent is reacted with the residual silanol groups and the residual silanol groups to be active sites may be reduced sufficiently.

Further, since the first silane coupling agent has plural hydrolytic groups, though new silanol groups derived from the first silane coupling agent may be formed, the second silane coupling agent also reacts with the silanol groups derived from the first silane coupling agent and the residual silanol groups to be active sites may be reduced.

Furthermore, since the second silane coupling agent has only one hydrolytic group, after the hydrolytic group reacts with the silanol group on the SiO₂ film surface or the silanol group derived from the first silane coupling agent, a new silanol group derived from the second silane coupling agent is no longer formed.

Therefore, according to the manufacturing method of the embodiment, silanol groups do not remain on the second orientation film in a large amount and the voltage change over time between the device substrate 10 and the opposed substrate 20 (between the pixel electrodes 12 and the common electrode 21) caused thereby may be suppressed. Thus, changes in display properties over time may be suppressed, and thereby, a liquid crystal display apparatus (liquid crystal display device) with high reliability may be manufactured.

Further, since the orientation film of the opposed substrate 20 (first orientation film 22) is formed by the coating process using the coating material, cost reduction may be realized.

Furthermore, since the treatment temperature at surface treatment using the second silane coupling agent is set lower than the treatment temperature at surface treatment using the first silane coupling agent, compounds derived from the first silane coupling agent may be prevented from desorbing from the inorganic orientation layer 15 at the surface treatment using the second silane coupling agent, and therefore, the function by the straight-chain alkyl groups R2 may be secured.

In addition, in the liquid crystal display apparatus (liquid crystal display device) obtained by the manufacturing method, the voltage change over time between the substrates (between the electrodes) is suppressed, and changes in display properties over time are also suppressed and reliability becomes higher.

The invention is not limited to the embodiment, however, various changes may be made without departing from the scope of the invention.

For example, in the embodiment, the invention is applied to the transmissive-type liquid crystal display apparatus, however, the invention is not limited thereto, but may be applied to a reflective-type or semi-transmissive-type liquid crystal display apparatus (liquid crystal display device) and a manufacturing method thereof.

Further, in the embodiment, the orientation film of the opposed substrate 20 is formed using the coating process and the orientation film of the device substrate 10 is formed using the vacuum process, however, in reverse, the orientation film of the opposed substrate 20 may be formed using the vacuum process and the orientation film of the device substrate 10 may be formed using the coating process.

### Experimental Example

As a liquid crystal panel according to the invention, a working example product and a comparative example product were fabricated using the same method as the manufacturing method of the above described embodiment.

Note that, in the manufacturing of the working example product, decyl trimethoxysilane with three hydrolytic groups was used as the first silane coupling agent and trimethyl methoxysilane with one hydrolytic group was used as the second silane coupling agent.

Further, in the manufacturing of the comparative example product, decyl trimethoxysilane was used as the first silane coupling agent and methyl trimethoxysilane with three hydrolytic groups was used as the second silane coupling agent.

Aging tests were respectively conducted on the obtained liquid crystal panels of the working example product and the comparative example product.

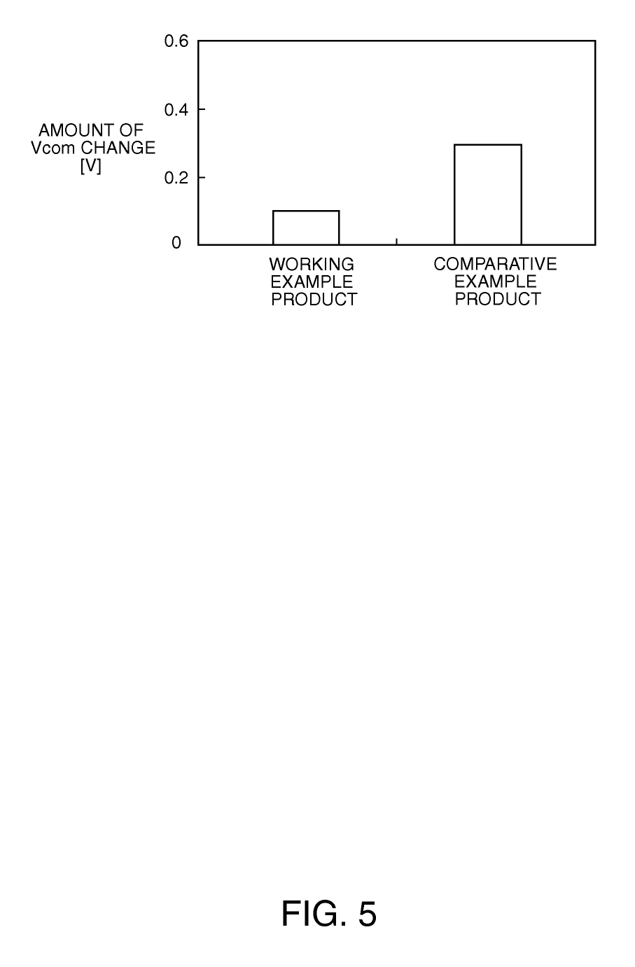

Vcom at the start of aging and Vcom at the end of aging (after a predetermined time has elapsed) were respectively measured and amounts of change were obtained. The obtained amounts of Vcom change are shown in FIG. 5.

As shown in FIG. 5, it was confirmed that, in the working example product using the agent with one hydrolytic group as the second silane coupling agent, the amount of Vcom change is smaller than that of the comparative example product, and thereby, the voltage change over time between the substrates (between the electrodes) is suppressed.

The entire disclosure of Japanese Patent Application No. 2010-234250, filed Oct. 19, 2010 is expressly incorporated by reference herein.

What is claimed is:

1. A manufacturing method of a liquid crystal display device including a liquid crystal layer sandwiched between a pair of opposed substrates with orientation films respectively provided between the pair of substrates and the liquid crystal layer, the method comprising:
forming a first orientation film having straight-chain alkyl chains using a coating process at the liquid crystal layer side of one substrate of the pair of substrates; and
forming a second orientation film at the liquid crystal layer side of the other substrate of the pair of substrates by forming an inorganic orientation layer using a vacuum process, and then, surface-treating the inorganic orientation layer using a silane coupling agent,
wherein forming the second orientation film includes surface-treating the inorganic orientation layer using a first silane coupling agent having straight-chain alkyl chains, and then, surface-treating the layer using a second silane coupling agent having straight-chain alkyl chains and having only one hydrolytic group.

2. The method according to claim 1, wherein a carbon number of the straight-chain alkyl chains of the second silane coupling agent is less than a carbon number of the straight-chain alkyl chains of the first silane coupling agent.

3. The method according to claim 1, wherein a treatment temperature at surface treatment using the second silane coupling agent is lower than a treatment temperature at surface treatment using the first silane coupling agent.

4. A liquid crystal display device comprising:
a liquid crystal layer sandwiched between a pair of opposed substrates with orientation films respectively provided between the pair of substrates and the liquid crystal layer;
a first orientation film having straight-chain alkyl chains formed using a coating process at the liquid crystal layer side of one substrate of the pair of substrates; and
a second orientation film at the liquid crystal layer side of the other substrate of the pair of substrates,
wherein the second orientation film is formed by surface-treating an inorganic orientation layer formed by a vacuum process using a first silane coupling agent having straight-chain alkyl chains, and then, surface-treating the layer using a second silane coupling agent having straight-chain alkyl chains and having only one hydrolytic group.
